(19) United States
(12) Patent Application Publication
(10) Pub. No.: US 2018/0298157 A1
(43) Pub. Date: Oct. 18, 2018

(54) Water Soluble Engraved Graphene and its Applications

(71) Applicant: HK INVESTMENT PRODUCTION TRADING, Ho Chi Minh City (VN)

(72) Inventors: Nguyen Khe, Ho Chi Minh City (VN); Vo H. Linh, Ho Chi Minh City (VN)

(73) Assignee: HK INVESTMENT PRODUCTION TRADING, Ho Chi Minh City (VN)

(21) Appl. No.: 15/490,842

(22) Filed: Apr. 18, 2017

(51) Int. Cl. C08K 3/04; C09D 11/037; C09D 11/322; C09D 11/52; H01L 51/00; H01M 10/0525; H01M 4/96; H01M 4/587; H01G 11/36; H01B 1/24

(52) U.S. Cl. CPC C08K 3/042; C09D 11/037; C09D 11/322; C09D 11/52; H01L 51/0048; H01B 1/24; C08K 3/041; H01M 10/0525; H01M 4/96; H01M 4/587; H01G 11/36; H01L 51/0047

(57) ABSTRACT

Certain exemplary embodiments can provide a system that comprises a product comprising a component. The component comprises water soluble engraved graphene, wherein the water soluble is an engraved graphene that comprises one or more chemically bonded water soluble functional groups. The water soluble engraved graphene is a graphene hybrid composite comprising graphene and multi-walled carbon nanotubes.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 is a scanning electron microscope (“SEM”) image of a carbon black and surface modified product (i.e., liquid Nanocoal;

FIG. 2 is an X-Ray diffraction chart of an exemplary sample of water soluble engraved graphene (“WSEG”) in accordance with an exemplary process disclosed herein;

FIG. 3 is a table that summarizes Brunauer, Emmett and Teller specific surface area measurement (“BET SSA”) of engraved graphene and WSEG;

FIG. 4 is Raman chart of an engraved graphene hybrid composite (“GHC”) and WSEG indicating the surface modifying chemistry only improves water solubility but not affecting physical structure of GHC;

FIG. 5 is a chart indicating the weight loss of WSEG under heat treatment at approximately 200 Celsius in a of WSEG atmosphere; and

FIG. 6 is a flowchart of an exemplary embodiment of a method.

### DETAILED DESCRIPTION

Certain exemplary embodiments can provide a system that comprises a product comprising a component. The component comprises water soluble engraved graphene, wherein the water soluble is an engraved graphene that comprises one or more chemically bonded water soluble functional groups. The water soluble engraved graphene is a graphene hybrid composite comprising graphene and multi-walled carbon nanotubes.

The surface modification of carbon black have been disclosed by Belmont et al., in U.S. Pat. No. 5,851,280, U.S. Pat. No. 5,554,739, U.S. Pat. No. 5,559,169, U.S. Pat. No. 5,571,311, and U.S. Pat. No. 5,575,845. According to these disclosures, water soluble groups such as —SO₃H, —COOH were grafted onto the surface of carbon black by diazo coupling reaction. The surface modified product becomes hydrophilic and exhibits stable dispersion in aqueous environment. From the standpoint of nanotechnology, diazo coupling is a chemical top down process, which breaks down micro particles of carbon black into nanoparticles due to a repulsion between particles carrying a charge of the same sign caused by the ionization of the surface by modifying species. The surface modified carbon black, can be called liquid nano coal (“LNC”).

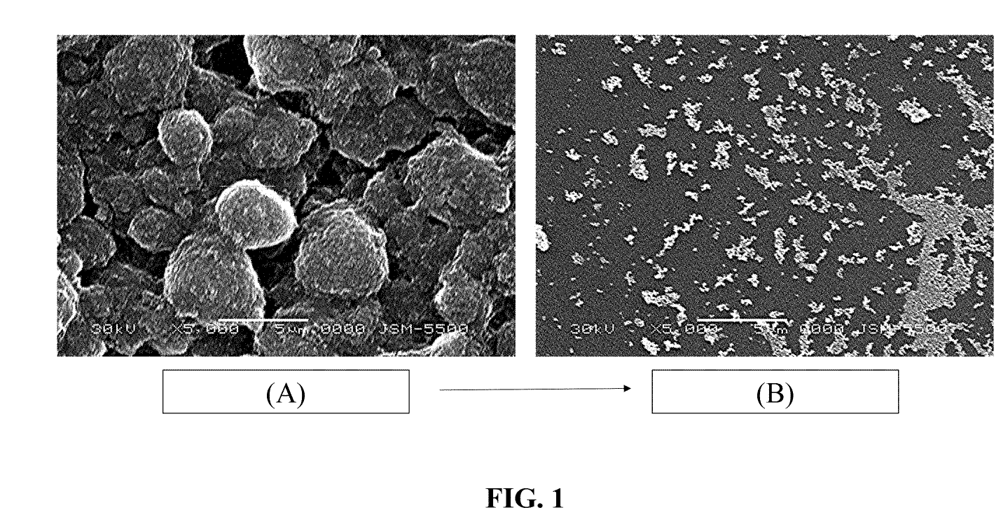

Certain exemplary embodiments provides surface modified carbon black having average particle size of approximately 25-30 nm which is 100 fold smaller than that of original carbon black raw material. FIG. 1 is a SEM image of original carbon black (A) showing average particle size of approximately 3 um while the surface modified carbon black by diazo coupling of sulfonic acid group-SO3H exhibits average particle size of approximately 25-30 nm.

The diazo coupling effect is one among multiple process which converts a hydrophobic surface into a hydrophilic surface, which selectively occurs with a solid state surface of sp2 and sp3 orbitals carrying specific functional group such as —OH, —SH, and/or —CO, etc. Diazo coupling reactions do not always occur with certain carbon materials.

The surface modification of carbon black or carbon materials can be detected via studying an optical density (“OD”) of an aqueous solution where surface modified carbon black has been added; the good coupling product shows good dispersion qualities exhibiting an OD of approximately 1.5 with approximately 5% by weight of carbon powder. A poor coupling product shows poor dispersion properties with relatively fast sedimentation after certain period from being agitated and leaves behind a clear supernatant.

Nanocarbon materials such as carbon nanotube and graphene exhibit exceptional mechanical properties, which look promising for reinforcement to improve material durability. A drawback of such materials can be that their inert surface can exhibit relatively poor compatibility with environment such as solvents, polymers, ceramics, and/or metals when blended. In order to overcome issues of incompatibility, desired functional groups can be grafted onto a surface to formulate polar materials, which might increase compatibility and miscibility in various media for varied applications comprising conductive ink, reinforcement nano filler, thermos-conductive sheet, and/or conductive lacquers, etc. However the chemical functionalization of inert surfaces can be challenging.

Water soluble graphene can be created via graphite oxidization into graphene oxide (GO), which exhibits solubility in water. However, some processes utilize a relatively large quantity of hazardous oxidizers such as H₂SO₄, HNO₃, KMnO₄, and thus can be somewhat environmentally challenging for large scale production.

In U.S. Pat. No. 9,460,827, Khe et al. disclosed a new type of GHC comprised of graphene and multi-walled carbon nano tubes (“MWNT”) prepared by chemical vapor deposition (“CVD”) processes utilizing solid state carbon precursors. This process is a safer way of making graphene in a much larger quantity compared to certain other thin film or chemical process.

In U.S. patent application Ser. No. 15/437,344 Khe et al. disclosed the process of engraved graphene exhibiting extra large SSA in the range of approximately 1500-2000 m²/g due to the nano porous surface comprised of super core generated by nano engraving process. An extra large SSA is desired for physical adsorption between different media and is suitable for multilayer electronic devices such as energy storage devices comprising super capacitors, batteries, and/or fuel cell catalysts, etc.

Certain exemplary embodiments provide an engraved graphene product having unique functional groups allowing high efficiency of diazo coupling. The engraved GHC exhibits strong adsorption of a diazo coupling agent prior to a reaction and enhances a coupling effect in combination with certain functional groups on GHC.

Certain exemplary embodiments provide a method that produces water soluble engraved graphene exhibiting water solubility. WSEG is a water soluble graphene hybrid composite (“WSGHC”) comprising an engraved graphene center surrounded with water soluble functional groups chemically grafted onto it. The WSEG shows a relatively large SSA and good dispersion as well as good compatibility with aqueous environment. Thus, WSEG is well blended in emulsion latex such as natural rubber latex. WSEG is also well blended with aqueous solutions of polymers.

Due to a relatively large SSA and a polar surface, WSEG can be miscible with many kinds of solvents to form products such as graphene ink and/or conductive ink, etc.

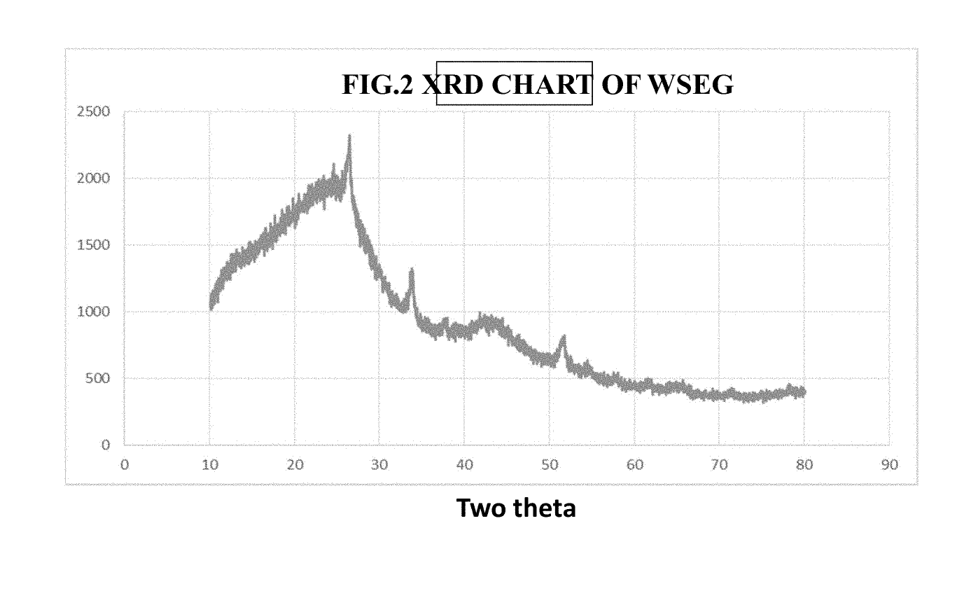

WSEG can also be miscible with any kinds of polymeric to formulate conducting composite, thermos conducting tape. In certain exemplary embodiments, WSEG, when analyzed via X-Ray diffraction, results in major diffraction peaks at two theta values of approximately 29 degrees, approximately 31 degrees, and approximately 46 degrees (see, e.g., FIG. 2).

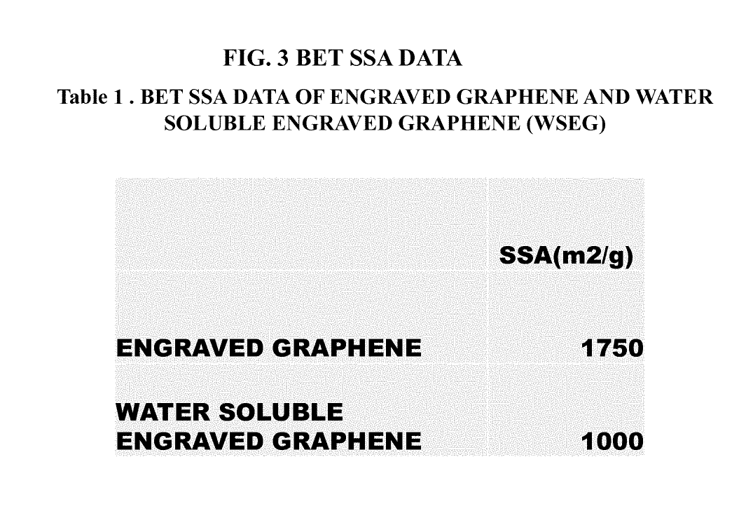

Certain exemplary embodiments can provide WSEG, which exhibits both hydrophilicity and large SSA. In FIG. 3, table 1 is summary of BET SSA data of starting engraved graphene and diazo coupling product (WSEG). One can see WSEG also exhibits large SSA of approximately 1000 m2/g indicating that the basic physical properties of engraved graphene exist in WSEG.

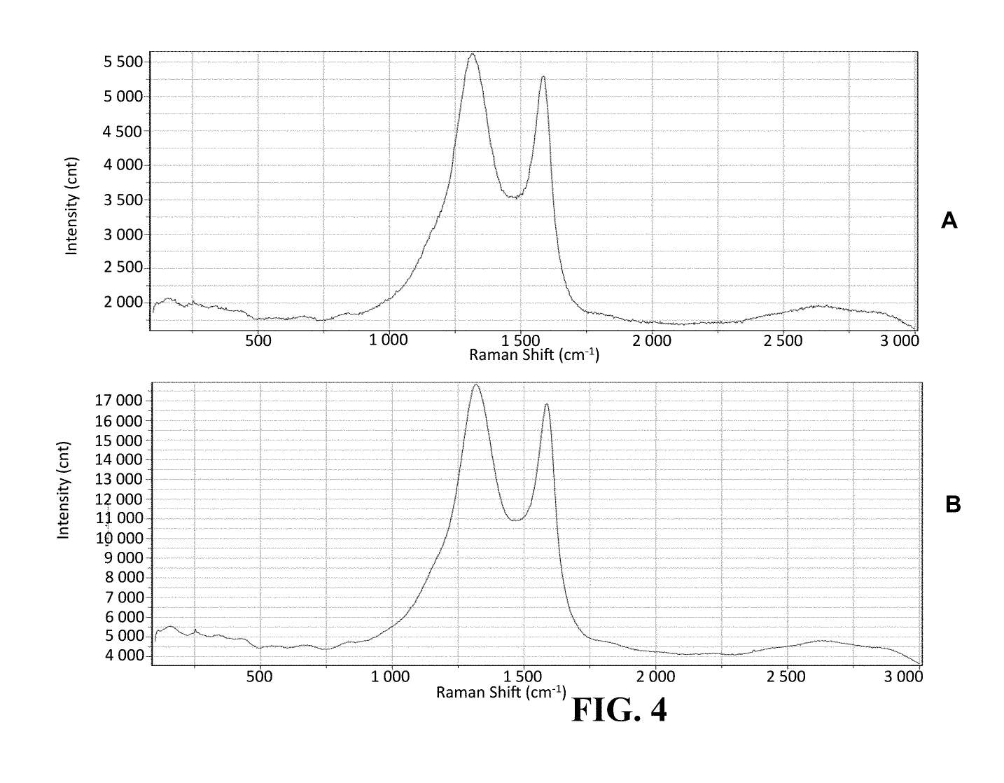

Certain exemplary embodiments can result in a Raman chart of both engraved graphene and correlating WSEG product (see, e.g., FIG. 4). One can see the similarity in Raman charts of both raw materials and final product, indicating that the basic physical properties of engraved graphene are also present in WSEG.

WSEG can be made by a process disclosed in U.S. Pat. No. 5,851,280. However, a specific engraved graphene as starting material must be selected to optimize the diazo coupling reaction.

In order to maximize the diazo coupling efficiency, the specific engraved graphene can be achieved. Besides a large SSA property, they can have chemical functional groups comprising —OH, —SH, and/or —CO, etc. These two combined requirements can be obtained with specific carbon sources comprising —O—, —OH, —CO, etc. via a specific catalyst and/or catalyst combination. The suitable catalysts can be selected from metal salts of elements belong to group I, II, III, VI, V in periodic chart table. Examples of catalysts are metal salts of organic and inorganic acids. Some catalysts or catalyst combination show better coupling effect than others.

Certain exemplary embodiments can provide engraved GHC having —CO, —OH, —SH groups by changing baking temperature and/or baking time during a GHC forming process.

The water soluble functional groups can comprise —OH, —SH, —COOH, —SO₃H, —NH₂ imidazole, benzimidazole, pyrrolidone, and/or pyridine, etc.

As a combination effect of both relatively large SSA and specific functional groups on GHC structure, certain WSEG products show a superior diazo coupling effect over relatively pure carbon nanotubes and graphene.

Certain exemplary embodiments can provide WSEG that exhibits relatively good water solubility when engraved graphene has an SSA that exceeds approximately 600 m²/g. The GHC showing SSA less than approximately 100 m²/g shows poor water solubility due to poor coupling efficiency.

Certain exemplary embodiments shows that the conventional carbon nanotube (“CNT”) products such as Graphistrength C100 (a product of the Arkema Group of Colombes France) could not undergo the diazo coupling even with relatively large quantities of sulfanilic acid. The coupling product failed to disperse in water and shows relatively fast sedimentation.

Certain exemplary embodiments also indicated that graphene nanoplatelets from Cheap Tubes Inc. (of Grafton, Vt.) and reduced graphene oxide (“RGO”) from graphene did not undergo diazo coupling reaction and as a result, the coupling products from these starting materials did not show proper dispersion properties.

Certain exemplary embodiments can provide an engraved graphene, which shows adequate diazo coupling effect over the non-engraved graphene. It has been observed that there is a big difference in dispersion behavior between low SSA sample (having an SSA of approximately 81 m²/g) and high SSA sample (having an SSA greater than approximately 1500 m²/g) of substantially the same surface chemistry. So it could be concluded that a large SSA in a combination with specific functional group enhances the effect of diazo coupling reaction giving rise to hydrophilic properties. In order to enhance the surface modification effect of graphene by diazo coupling, the surface of graphene can be relatively large and comprise a lot of nanopores for relatively strong adsorption prior to reaction.

Certain exemplary embodiments can provide hydrophilic engraved graphene showing relatively good dispersion in the water. The hydrophilic engraved graphene shows relatively good dispersion in natural rubber latex, which is an emulsion comprising approximately 60% solids, to form a composite suitable for rubber compounding and reinforcement.

Under heat treatment at approximately 160-200 Celsius in an atmosphere of WSEG, hydrophilic engraved graphene shows a weight loss and a water solubility that decreased, which indicates a cleavage of a water soluble functional group off the engraved graphene to go back to an original engraved graphene structure. It is also indicating that the diazo coupling is temporary to help out the dispersion and then, the coupling functionality can be emitted off of the engraved graphene surface. In rubber compounding for tires, such embodiments match relatively well with the curing process.

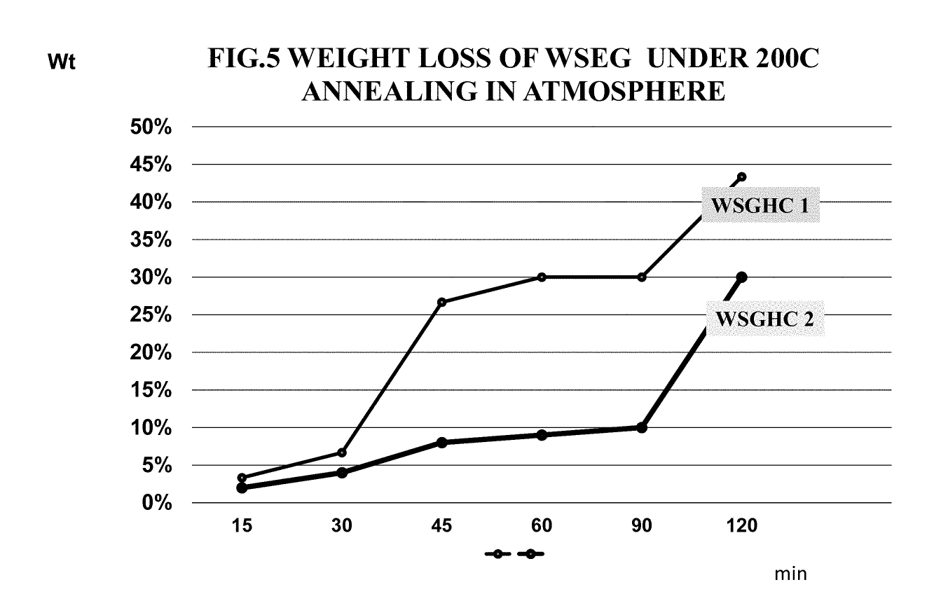

FIG. 5 shows weight loss effect by heating at approximately 200 degrees Celsius in an atmosphere of WSEG.

FIG. 4 is Raman chart of engraved GHC and WSEG indicating the surface modifying chemistry doesn't significantly affect key physical properties of engraved graphene. Chart A is from engraved graphene G4201510-38_3 as a starting material. Chart B is for WSGHC LNC201512_36_2 as a surface modified engraved graphene product.

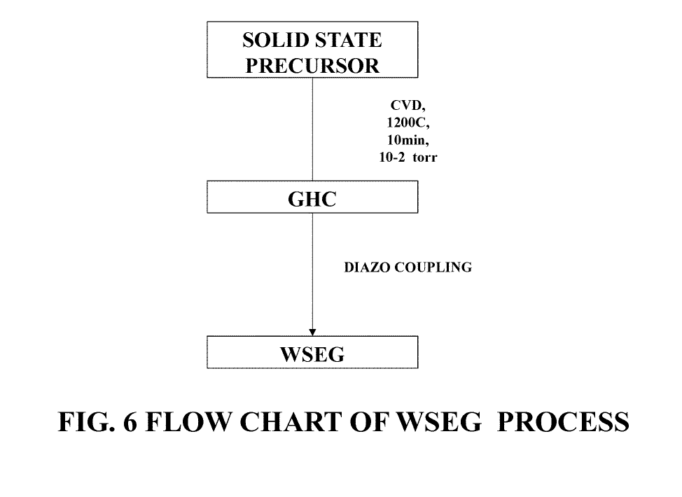

FIG. 6 is a flowchart of an exemplary embodiment of a method 9000.

FIG. 1 is an SEM image of carbon black and surface modified product (e.g., LNC). Image A is of carbon black. Image B is of a surface modified product (LNC) at a magnification of ×5000. The surface modification was via diazo coupling (i.e., a Chemical Top Down Nano Process).

FIG. 2 is an X-Ray Diffraction chart of an exemplary sample of WSEG in accordance with an exemplary process disclosed herein.

FIG. 3 is a table summarizing BET SSA of engraved graphene and WSEG.

FIG. 4 is Raman chart of engraved GHC and WSEG indicating the surface modifying chemistry only improves water solubility but not affecting physical structure of GHC.

FIG.5 is a chart indicating the weight loss of WSEG under heat treatment at 200 C at atmosphere.

Certain exemplary embodiments provide a product comprising a component. The component can comprise water soluble engraved graphene. The water soluble engraved graphene comprises one or more chemically bonded water soluble functional groups. The water soluble engraved graphene can be a graphene hybrid composite comprising graphene and multi-walled carbon nanotubes. The multi-walled carbon nanotubes in the engraved graphene are less than 10% by weight. The graphene hybrid composite can have a specific surface area greater than 2000 m²/g. The water soluble engraved graphene can have a specific surface area that is greater than approximately 2000 m²/g. The engraved graphene can comprises one or more of a thin film graphene, a graphene nano platelet, graphene oxide, reduced graphene oxide, fullerene, and graphite. The one or more water soluble functional groups can comprise one or more of —SO3H, —COOH, —OH, —CO, —NH2, —SH, imidazole, benzimidazole, pyrrolidinone, and pyridine. The water soluble engraved graphene can be convertible to engraved graphene by at least one of heat and light. When analyzed via X-Ray Diffraction, the water soluble engraved graphene has major diffraction peaks at two theta values of approximately 29 degrees, approximately 31 degrees, and approximately 46 degrees.

The water soluble engraved graphene can be used as a nanofiller used to reinforce plastic, rubber, polymer, ceramic, cement, metals. The water soluble engraved graphene can be a temporary helper in a dispersion method, wherein water soluble functional groups leave off the water soluble engraved graphene during blending.

The water soluble engraved graphene can be a nanofiller used to formulate thermo-conducting or electro-conducting matter. The water soluble engraved graphene can be comprised by one or more of inkjet printing ink and xerographic printing ink as a colorant. The water soluble engraved graphene can be a precursor for conductive ink, electronic devices, or a solar cell.

The product can be an electronic multi layer device, an energy storage multi layer device, a supercapacitor, a fuel cell catalyst, and/or a lithium ion battery, etc. The product can comprise an elastomer. The water soluble engraved graphene can be used as an interface material for a multi-layer device.

FIG. 6 is a flowchart of an exemplary embodiment of a method. The method can comprise producing a water soluble engraved graphene, wherein:
the water soluble engraved graphene is a graphene hybrid composite comprising graphene and multi-walled carbon nano tubes;
the multi-walled carbon nano tubes in the engraved graphene are less than 10% by weight;
the graphene hybrid composite has specific surface area greater than 2000 m2/g;
the water soluble engraved graphene has a specific surface area that is greater than 2000 m2/g;
the engraved graphene is comprises one or more of a thin film graphene, graphene hybrid composite, a graphene nano platelet, graphene oxide, reduced graphene oxide, fullerene, and graphite;
the one or more water soluble functional groups comprise one or more of —SO3H, —COOH, —OH, —CO, —NH2, —SH, imidazole, benzimidazole, pyrrolidinone, and pyridine.
the water soluble engraved graphene is convertible to engraved graphene by at least one of heat and light; and
when analyzed via X-Ray Diffraction, the water soluble engraved graphene has major diffraction peaks at two theta values of approximately 29 degrees, approximately 31 degrees, and approximately 46 degrees.

The water soluble engraved graphene can be produced via a nanoengraving method. The water soluble engraved graphene can be used in a combination with one or more of rubber, silica, aerogel silica, carbon black, mineral oils, and/or mineral salts, etc.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
acid—a molecule or ion capable of donating a hydron (proton or hydrogen ion H+), or, alternatively, capable of forming a covalent bond with an electron pair.
activated carbon—charcoal that has been heated or otherwise treated to increase its adsorptive capacity.
activity—an action, act, step, and/or process or portion thereof.
aerogel silica—a synthetic porous ultralight material derived from a gel, in which the liquid component of the gel has been replaced with a gas. The result is a solid with extremely low density and low thermal conductivity.
analyze—to ascertain of a kind or amount of one or more of the constituents of a material, whether obtained in separate form or not.
and/or—either in conjunction with or in alternative to.
apparatus—an appliance or device for a particular purpose.
article—a particular item or object.
associate—to join, connect together, and/or relate.
average—a number expressing a central or typical value in a set of data, in particular the mean, which is calculated by dividing the sum of the values in the set by their number.
battery electrode—an electrical conductor used to make contact with a nonmetallic part of an electrochemical cell, wherein the electrochemical cell is adapted to convert chemical energy to electrical energy.
BET specific surface area—a measurement of an absorption capability of an exposed portion of a substance, the measurement is named after the researchers Brunauer, Emmett, and Teller.
blend—to mix together.
buckminsterfullerene—a form of carbon having molecules of 60 atoms arranged in a polyhedron resembling a geodesic sphere.
building—a structure with a roof and walls, such as a house, school, store, or factory.
can—is capable of, in at least some embodiments.
carbon black—a fine particulate form of carbon powder used as a pigment, made by burning hydrocarbons in insufficient air.
carbon source—a substance that provides carbon to synthesize graphene.
catalyst—a chemical that accelerates chemical reaction.
cause—to produce an effect.
cellulose—an insoluble substance that is the main constituent of plant cell walls and of vegetable fibers such as cotton.
ceramic—a material made of clay and hardened by heat.
ceramic powder—fine particles of an inorganic, nonmetallic solid material comprising metal, nonmetal or metalloid atoms primarily held in ionic and covalent bonds.
charge accumulative material—a substance that is able to store an electrical potential difference between a first portion of the substance and the second portion of the substance.
charge transfer interface—a boundary between two substances across which electrons move.
chemical bond—a physical phenomenon of substances being held together by attraction of atoms.
chemical stability—when a system is in substantial chemical equilibrium with its environment.
chemically—via a chemical reaction.
comprising—including but not limited to.
conductive—capable of transmitting electricity with relatively low resistance.
configure—to make suitable or fit for a specific use or situation.
constructed to—made to and/or designed to.
convert—to transform, adapt, and/or change.
corrosion agent—a substance that causes destruction by chemical action.
cosmetic powder—a substance comprising fine particles that is used to attempt to enhance beauty.
crack—to break without a complete separation of the parts.
create—to bring into being.
curer—to vulcanize (rubber).
define—to establish the outline, form, or structure of
device—a machine, manufacture, and/or collection thereof.
diamond—a stone comprising substantially pure carbon, having an optically translucent crystalline form, and being the hardest naturally occurring known substance.
diazonium—a group of organic compounds sharing a common functional group R—N₂⁺X⁻where R can be any organic group, such as an alkyl or an aryl, and X is an inorganic or organic anion, such as a halogen.
dispersion—a method via which particles are dispersed in a substantially continuous phase of a different composition.
dissolution—a process by which two substances form a solution.
durability—an ability to withstand wear, pressure, or damage.
elastomer—a polymer with viscoelasticity (having both viscosity and elasticity) and very weak inter-molecular forces, generally having low Young's modulus and high failure strain compared with other materials.
electro-conducting—capable of readily conducting electricity.
electrocatalyst—a chemical that accelerates an electrochemical reaction.
electronic device—equipment that operates via electrical energy.
energy storage—capable of retaining a capability to do work.
engrave—to carve or etch a material in a manner that increases surface porosity.
fine particles—solids that have a maximum dimension between 100 and 2,500 nanometers.
fluid absorbing solid—a particulate substance into which atoms, molecules or ions of a liquid enter.
form—to make something.
formulate—to prepare via a recipe and method.
fuel cell—a device that converts the chemical energy from a fuel into electricity through a chemical reaction of positively charged hydrogen ions with an oxidizing agent.
fullerene—a molecule of carbon in the form of a hollow sphere, ellipsoid, tube, and many other shapes.
functional group—a group of atoms responsible for the characteristic reactions of a particular compound.
gas—a fluid substance, which expands freely to fill any space available, irrespective of its quantity.
gas absorbing solid—a particulate substance upon a surface of which atoms, molecules or ions of a gas are held.
gas forming agent—an element or compound that causes generation of a gas.
generate—to create, produce, give rise to, and/or bring into existence.
graphene—an allotrope of carbon in the form of a two-dimensional, atomic-scale, hexagonal lattice in which one atom forms each vertex.
graphene—solids that comprise only fine particles or nano particles that comprise a partially substantially planar surface.
graphene flower—graphene synthesized in a manner that causes the graphene to have an appearance similar to a flower immediately after synthesis.
graphene hybrid composite—a substance comprising graphene as described in U.S. Pat. No. 9,460,827, which substance comprises carbon nanotubes.
graphite—a gray, crystalline, allotropic form of carbon.
heat—added or external energy that causes a rise in temperature, expansion, evaporation, or other physical change.
incorporate—to unite substances.
inject—to insert by force into something.
ink—a liquid or paste that contains pigments and/or dyes.
inkjet—a system constructed to propel droplets of ink onto paper, plastic, or other substrates.
inkjet printing—a type of computer printing that recreates a digital image by propelling droplets of ink onto paper, plastic, or other substrates.
interface material—a substance present at a surface regarded as a boundary between two portions of a system.
iodonium—any onium compound (ion) containing an iodine atom carrying a positive charge.
light—electromagnetic radiation to which the organs of sight react, ranging in wavelength from approximately 400 to 700 nm and propagated at a speed of approximately 299,972 km/sec.
lithium ion battery—a type of rechargeable battery in which lithium ions move from the negative electrode to the positive electrode during discharge and back when charging.
major diffraction peak—a relatively high level of measured diffracted X-Ray intensity at a given angle of application.
major diffraction peak—a significant upward deviation on a spectral plot measured via X-Ray Diffraction.
may—is allowed and/or permitted to, in at least some embodiments.
metal—a solid material that is typically hard, shiny, malleable, fusible, and ductile, with good electrical and thermal conductivity (e.g., iron, gold, silver, copper, and aluminum, and alloys such as brass and steel).
method—a process, procedure, and/or collection of related activities for accomplishing something.
mineral oil—any of various colorless, odorless, light mixtures of higher alkanes from a mineral source, particularly a distillate of petroleum.
mineral salt—inorganic ionic compounds that result from a neutralization reaction of an acid and a base that comprise trace elements found in animals.
mix—to combine two or more substances.
molecule—a smallest unit of a chemical compound.
multi-layer device—a device that comprises a component made via sequential deposition of groups of molecules of different substances on a substrate or base.
multi-walled carbon nanotube—a carbon nanotube that comprises concentric tubes of graphene.
nanoadditive—a substance that has a maximum dimension between 1 and 100 nanometers.
nanocarbon—carbon nanoparticles.
nanoengraving—engraving a nanoparticle.
nanofiller—a doping agent distributed in the matrix of a composite, whose individual elements have at least one of their dimensions in the nanoscale.
nanoparticles—solids that have a maximum dimension between 1 and 100 nanometers.
nanoplatelet—a disk-shaped nanoparticle.
nanotube—a nanoparticle of carbon that comprises a substantially cylindrical portion.
nanowire—a nanostructure, with a diameter on the order of a nanometer (10⁻⁹ meters) and having a ratio of the length to width being greater than 1000.
opaque—substantially impervious to light transmission.
organic—derived from living matter.
oxidizing agent—an element or compound in a redox reaction that absorbs an electron donated by another species.
particle—a tiny piece of matter.
particle size—a largest dimension of a solid minute portion of matter.
pharmaceutical powder—a substance comprising fine particles that is used by humans to treat one or more health issues.
physically—not via any significant chemical reaction.
plurality—the state of being plural and/or more than one.
polymer—a substance that has a molecular structure consisting primarily or entirely of a large number of similar units bonded together.
pore size—a diameter of a hole defined by a surface.
precursor—a chemical compound preceding another.
predetermined—established in advance.
pressure—the exertion of force upon a surface by an object, fluid, etc., in contact with it.
printing—the production of books, newspapers, or other printed material.
produce—to make.
provide—to furnish, supply, give, and/or make available.
pyridine—a basic heterocyclic organic compound with the chemical formula C5H5N. It is structurally related to benzene, with one methine group (═CH—) replaced by a nitrogen atom.
pyrrolidinone—an organic compound consisting of a 5-membered lactam, making it the simplest γ-lactam. It is a colorless liquid that is miscible with water and most common organic solvents.
react—to transform one set of chemical substances to another.
reaction chamber—an enclosed vessel in which one set of chemical substances is transformed to another.
receive—to get as a signal, take, acquire, and/or obtain.
reducing agent—an element or compound in a redox reaction that donates an electron to another species.
reinforcement additive—a substance that is added to something, which substance improves a physical strength or stiffness of the something to which the substance is added.
release—to emit.
remove—to rid of.
resistance—an ability not to be affected adversely by something.
rice husk—a hard protecting coverings of grains of rice.
rubber—a substance comprising polymers of the organic compound isoprene.
salt—any chemical compound formed from the reaction of an acid with a base, with all or part of the hydrogen of the acid replaced by a metal or other cation.
SC nanocomposite—a silica/acid composite comprising nanoparticles.
select—to make a choice or selection from alternatives.
semiconductor—a crystalline or amorphous solids with an electrical resistance that is higher than typical resistance materials, but still of much lower resistance than insulators. Their resistance decreases as their temperature increases, which is behavior opposite to that of a metal. Semiconductor conducting properties may be altered in useful ways by the deliberate, controlled introduction of impurities (“doping”) into the crystal structure, which lowers electrical resistance but also permits the creation of semiconductor junctions between differently-doped regions of the extrinsic semiconductor crystal. The behavior of charge carriers, which include electrons, ions and electron holes at these junctions, is the basis of diodes, transistors and all modern electronics.
set—a related plurality.
silica hydrogel—a matrix of substantially pure silicon dioxide and water that is a free flowing and can be finely ground into a white powder.
silica/acid composite—a substance comprising a silica core and having a specific acidic shell. The substance having an X-ray diffraction chart with diffraction peaks appearing at approximately a two theta value approximately equal to 2 degrees, 27.75 degrees, and 41 degrees.
solar cell—a system that converts energy from the sun into electricity.
solvent—a substance that is able to dissolve other substances.
specific acid—an acid selected for a specific function.
specific surface area—a property of solids defined as the total surface area of a material per unit of mass.
substantially—to a great extent or degree.
super pores—holes defined in a surface such that the BET specific surface area of the surface is greater than approximately 1,500 square meters per gram.
supercapacitor—a high-capacity electrochemical capacitor with capacitance values much higher than other capacitors (but lower voltage limits) that bridge a gap between electrolytic capacitors and rechargeable batteries. Supercapacitors utilize use electrostatic double-layer capacitance or electrochemical pseudocapacitance. Supercapacitors have a range of capacitances between approximately 0.001 F and approximately 6,000 F. Supercapacitors have cell voltages ranging between approximately 1.4 volts and approximately 125 volts.
surface—an outer portion of a substance.
surface modified carbon—carbon black that has been chemically modified with specific functional groups. Cab-o-jet 200 and Cab-o-jet 300 are examples of surface modified carbon black,
system—a collection of mechanisms, devices, machines, articles of manufacture, processes, data, and/or instructions, the collection designed to perform one or more specific functions.
temporary helper—a process aid that is transformed in the process after a period of time.
thermo-conducting—capable of readily conducting heat.
thin film—ten layers or less of graphene sheets.
thiopyrylium—a cation with the chemical formula C₅H₅S⁺.
toughness—an ability of a material to absorb energy and plastically deform without fracturing.
translucent—permitting light to pass through but diffusing the light so that persons, objects, etc., on an opposite side are not clearly visible.
two theta—a detector swing angle of an X-ray diffraction system is defined as “two theta”.
via—by way of and/or utilizing.
water soluble—capable of being dissolved in a solvent that comprises H₂O.
wear—to damage by friction or use.
weight—a value indicative of importance.
wood—a hard fibrous material that forms the main substance of the trunk or branches of a tree or shrub.
X-Ray Diffraction—a method of analyzing substances that measures a scattered intensity of an X-ray beam hitting a sample as a function of incident and scattered angle, polarization, and wavelength or energy.
xerographic printing—a type of computer printing based on the principle of xerography or electrophotography; xeroprinting creates multiple prints using one latent image, which had been electronically memorized on print media via ink or toner.
zeolite—a microporous, aluminosilicate mineral.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
a product comprising a component, said component comprising water soluble engraved graphene, said water soluble engraved graphene comprising one or more chemically bonded water soluble functional groups, wherein:
said water soluble engraved graphene is a graphene hybrid composite comprising graphene and multi-walled carbon nanotubes;
said multi-walled carbon nanotubes in said engraved graphene are less than 10% by weight;
said graphene hybrid composite has specific surface area greater than 2000 m²/g;
said water soluble engraved graphene has a specific surface area that is greater than 2000 m²/g
said engraved graphene comprises one or more of a thin film graphene, a graphene nano platelet, graphene oxide, reduced graphene oxide, fullerene, and graphite;
said one or more water soluble functional groups comprise one or more of —SO₃H, —COOH, —OH, —CO, —NH₂, —SH, imidazole, benzimidazole, pyrrolidinone, and pyridine;
said water soluble engraved graphene is convertible to engraved graphene by at least one of heat and light; and
when analyzed via X-Ray Diffraction, said water soluble engraved graphene has major diffraction peaks at two theta values of approximately 29 degrees, approximately 31 degrees, and approximately 46 degrees.

2. The system of claim 1, wherein:
said water soluble engraved graphene is used as one or more of a nanofiller and nanoadditive used to reinforce plastic, rubber, polymer, ceramic, cement, metals.

3. The system of claim 1, wherein:
said water soluble engraved graphene is a temporary helper in a dispersion method, wherein water soluble functional groups leave off said water soluble engraved graphene during blending.

4. The system of claim 1, wherein:
said water soluble engraved graphene is a nanofiller used to formulate thermo-conducting or electro-conducting matter.

5. The system of claim 1, wherein:
said water soluble engraved graphene is comprised by one or more of inkjet printing ink and xerographic printing ink as a colorant.

6. The system of claim 1, wherein:
said water soluble engraved graphene is a precursor for conductive ink, electronic devices, or a solar cell.

7. The system of claim 1, wherein:
said product is an electronic multi layer device.

8. The system of claim 1, wherein:
said product is an energy storage multi layer device.

9. The system of claim 1, wherein:
said product is a supercapacitor.

10. The system of claim 1, wherein:
said product is a fuel cell catalyst.

11. The system of claim 1, wherein:
said product is a lithium ion battery.

12. The system of claim 1, wherein:
said product comprises an elastomer.

13. The system of claim 1, wherein:
said water soluble engraved graphene is used as an interface material for a multi-layer device.

14. A method comprising:
producing a water soluble engraved graphene, wherein:
said water soluble engraved graphene is a graphene hybrid composite comprising graphene and multi-walled carbon nano tubes;
said multi-walled carbon nano tubes in said engraved graphene are less than 10% by weight;
said graphene hybrid composite has specific surface area greater than 2000 m²/g;
said water soluble engraved graphene has a specific surface area that is greater than 2000 m²/g
said engraved graphene is comprises one or more of a thin film graphene, graphene hybrid composite, a graphene nano platelet, graphene oxide, reduced graphene oxide, fullerene, and graphite;
said one or more water soluble functional groups comprise one or more of —SO₃H, —COOH, —OH, —CO, —NH₂, —SH, imidazole, benzimidazole, pyrrolidinone, and pyridine;
said water soluble engraved graphene is convertible to engraved graphene by at least one of heat and light; and
when analyzed via X-Ray Diffraction, said water soluble engraved graphene has major diffraction peaks at two theta values of approximately 29 degrees, approximately 31 degrees, and approximately 46 degrees.

15. The method of claim 14, wherein:
said water soluble engraved graphene is produced via a nanoengraving method.

16. The method of claim 14, wherein:
said water soluble engraved graphene is used in combination with one or more of rubber, silica, aerogel silica, carbon black, mineral oil, and mineral salts.
